(19) United States
(12) Patent Application Publication
(10) Pub. No.: US 2004/0136165 A1
(43) Pub. Date: Jul. 15, 2004

(54) Mainframe case with sliding cover openable in multiple stages

(75) Inventor: Jung-hua Wang, Sanchung City (TW)

Correspondence Address: BACON & THOMAS, PLLC, 625 SLATERS LANE, FOURTH FLOOR, ALEXANDRIA, VA, 22314

(73) Assignee: SAN HUA METAL CO., LTD., Sanchung City (TW)

(21) Appl. No.: 10/350,046

(22) Filed: Jan. 24, 2003

(51) Int. Cl. H05K 7/16; A47B 97/00

(52) U.S. Cl. 361/727; 312/223.2

(57) ABSTRACT

A mainframe case includes a sliding cover connected thereto through sliding engagement of first-stage sliding rails slidably mounted in two fixed channels on the mainframe case with second-stage sliding rails fixedly mounted on the cover corresponding to the fixed channels. An intermediate sliding rail is mounted between the first-stage and second-stage sliding rails to slide relative to the first-stage and the second-stage sliding rails. To open the cover for maintenance, repair, and replacement of hardware in the mainframe case, simply pull it relative to the mainframe case in a predetermined direction, and the first-stage sliding rails, the intermediate sliding rails, and the second-stage sliding rails are sequentially brought to slide in the same direction to locate the cover at an open position without completely separating from the mainframe case. And the cover may be conveniently pushed in reverse direction to slide back to a close position again.

### FIELD OF THE INVENTION

The present invention relates to a mainframe case with sliding cover openable in multiple stages. The mainframe case is provided at one side with fixed channels, in which first-stage sliding rails are slidably mounted, and the sliding cover is provided with second-stage sliding rails corresponding to and slidable relative to the first-stage sliding rails, so that the cover may be easily pulled open in multiple stages when the first-stage and the second-stage sliding rails sequentially slide away from the fixed channels without completely separating from one another.

### BACKGROUND OF THE INVENTION

Most currently available mainframe cases have a back cover that must be opened and removed when it is desired to maintain, repair, or replace components mounted in the mainframe case. To open the back cover, it is necessary to loosen some screws therefrom and is therefore very troublesome. There are also mainframe cases having a cover that is connected to the mainframe case through engagement of, for example, elastic male and female connectors separately provided on the mainframe case and the cover. While such type of cover can be directly disengaged from the mainframe case conveniently, it is, however, uneasy to remount it to the mainframe case, particularly for operators who are not skilled in assembling the mainframe case, because all the elastic male and female connectors must be accurately aligned with one another to enable remounting of the cover to the mainframe case.

It is therefore desirable to develop a mainframe case having a cover that can be easily opened or closed to eliminate the drawbacks existed in the conventional mainframe cases.

### SUMMARY OF THE INVENTION

A primary object of the present invention is to provide a mainframe case with sliding cover openable in multiple stages without completely separating from the mainframe case, so as to facilitate maintenance, repair, and replacement of hardware in the mainframe case.

To achieve the above and other objects, the mainframe case according to the present invention includes a sliding cover connected thereto through movable engagement of first-stage sliding rails slidably mounted in two fixed channels on the mainframe case with second-stage sliding rails fixedly mounted on the cover corresponding to the fixed channels. An intermediate sliding rail is mounted between the first-stage and second-stage sliding rails to slide relative to the first-stage and the second-stage sliding rail. To open the cover for maintenance, repair, and replacement of hardware in the mainframe case, simply pull it relative to the mainframe case in a predetermined direction, and the first-stage sliding rails, the intermediate sliding rails, and the second-stage sliding rails are sequentially brought to slide in the same direction to locate the cover at an open position without completely separating from the mainframe case. And the cover may be conveniently pushed in reverse direction to slide back to a close position again.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a perspective view showing an overall structure of the present invention;

FIG. 2 is an enlarged sectional view showing the relative positions of a first-stage sliding rail, an intermediate sliding rail, and a second-stage sliding rail for the present invention;

FIG. 3 is a side view of the first-stage sliding rail of the present invention;

FIG. 4 is top view of the first-stage sliding rail of the present invention;

FIG. 5 is a top view of the second-stage sliding rail of the present invention;

FIG. 6 is a side view of the second-stage sliding rail of the present invention;

FIG. 7 is a fragmentary vertical sectional view showing a locking assembly of the present invention; and

FIG. 8 is a fragmentary sectional view showing the relative positions of the first-stage sliding rail and a hooked spring strip in a fixed channel of the present invention.

### DETAILED DESCRIPTION OF THE PREFERRED EMBODIMENTS

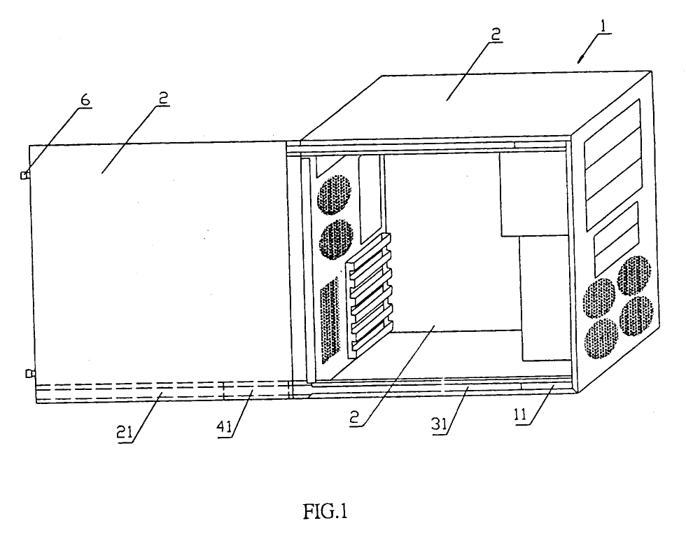

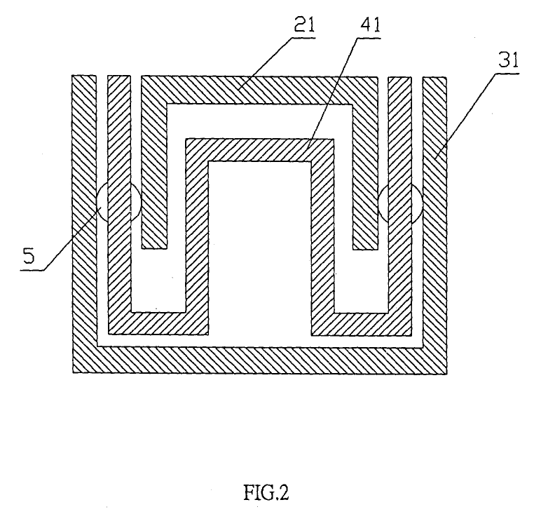

Please refer to FIG. 1 in which a computer mainframe case 1 having a sliding cover 2 openable in multiple stages is shown. As can be seen from FIG. 1, the mainframe case 1 is provided at upper and lower edges of one side to where the sliding cover 2 is mounted with a pair of outward-faced fixed channels 11. Each of the fixed channels 11 has a first-stage sliding rail 31 mounted therein to slide relative to the fixed channel 11. The cover 2 is provided at inner upper and inner lower edges corresponding to the two fixed channels 11 with two second-stage sliding rails 21. Please refer to FIG. 2. Each second-stage sliding rail 21 is slidable in and relative to the corresponding first-stage sliding rail 31. To open the cover 2, simply pull it rearward so that the second-stage sliding rails 21 move along the first-stage sliding rails 31. It is to be noted that the first-stage sliding rails 31 move rearward along the fixed channels 11 when the cover 2 is pulled rearward. That is, the first-stage sliding rails 31 are actually extensions of the two fixed channels 11 to enable the cover 2 to be opened without being completely separated from the mainframe case 1. This means the opened cover 2 may be closed to the mainframe case 1 simply by pushing it forward along the first-stage sliding rails 31 and the fixed channels 11. The sliding cover 2 can therefore be very conveniently opened and closed relative to the mainframe case 1 to facilitate hardware maintenance, repair, and replacement of a computer.

As shown in FIG. 2, an intermediate sliding rail 41 is further slidably mounted between two corresponding first-stage and second-stage sliding rails 31, 21 to move relative to both the sliding rails 31, 21. Each of the intermediate sliding rails 41 has slide-assisting means mounted thereon, such as, for example, balls 5. The balls 5 are rotatably in contact with inner wall surfaces of the first-stage and the second-stage sliding rails 31, 21, enabling the cover 2 to be pulled and pushed in a smoother manner.

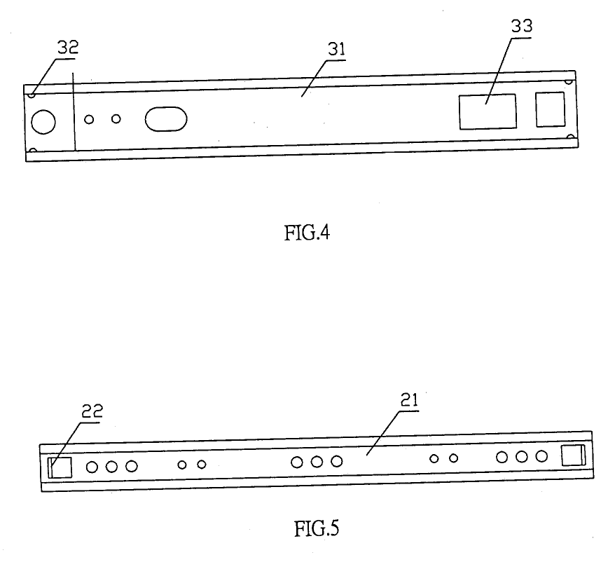

Please refer to FIGS. 4 and 8 at the same time. Each first-stage sliding rail 31 is formed near a front end with a stop opening 33, and a hooked spring strip 12 having a flat long segment 121 and a bent short segment 122 is removably mounted in each fixed channel 11 at a predetermined position (see FIG. 8). When the cover 2 is pushed forward to a close position on the mainframe case 1, the first-stage sliding rails 31 are moved into the fixed channels 11 at the same time. In this position, each of the first-stage sliding rails 31 has a bottom surface pressed against an upper side of the flat long segment 121 of the spring strip 12. When the cover 2 in the close position is pulled rearward, each first-stage sliding rail 31 is caused to slide rearward and then stopped from moving any further when the stop opening 33 passes the spring strip 12 and a hook formed by the bent segment 122 springs upward to abut on a front edge of the stop opening 33. The abutment of the bent segment 122 of the spring strip 12 on the front edge of the stop opening 33 prevents the first-stage sliding rail 31 from sliding off and completely separating from the fixed channel 11.

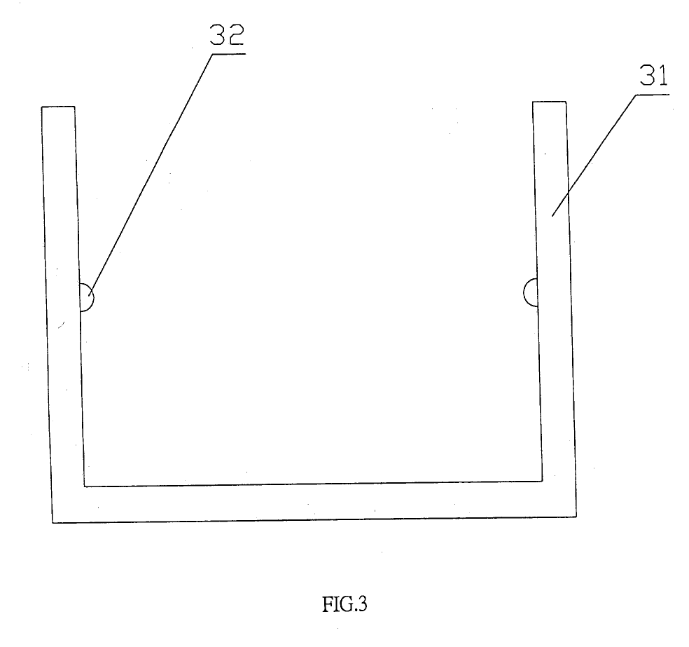

Please refer to FIGS. 3 and 4 at the same time. Each first-stage sliding rail 31 is provided close to both ends with stop means for preventing the intermediate sliding rail 41 from completely sliding off and therefore separating from the first-stage sliding rail 31. The stop means may be, for example, two pairs of opposite protrusions 32 provided on two inner walls of the first-stage sliding rail 31 to project into the sliding rail 31.

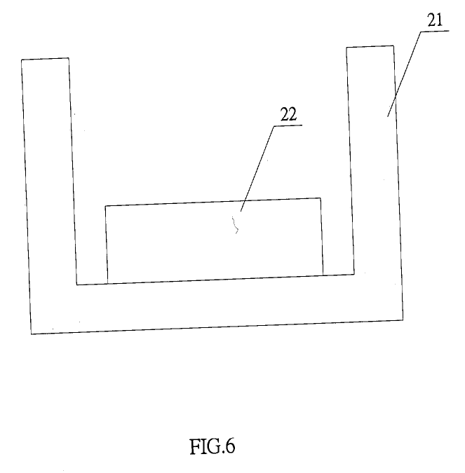

As can be seen from FIGS. 5 and 6, each second-stage sliding rail 21 is also provided close to both ends with stop means for preventing the second-stage sliding rail 21 from completely sliding off and therefore separating from the intermediate sliding rail 41. The stop means on the second-stage sliding rails 21 may be, for example, upward projected stop plates 22 formed by punching from a bottom of each second-stage sliding rail 21.

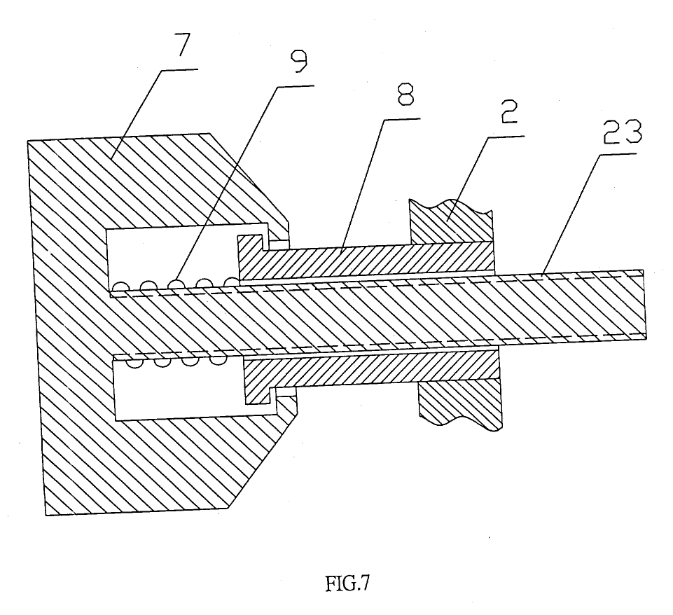

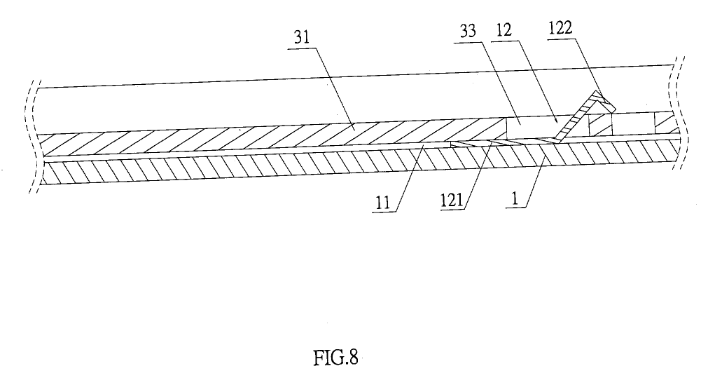

Please refer back to FIG. 1. There are locking assemblies 6 provided at a rear edge of the cover 2 for locking the cover 2 in the close position to the mainframe case 1. FIG. 7 is an enlarged sectional view of one locking assembly 6. As shown, each locking assembly 6 includes a turning head 7, a collar 8 fixedly connected to the cover 2, and a spring 9. The turning head 7 is fixedly connected to a screw 23, which is extended through the collar 8 into a threaded hole (not shown) correspondingly formed on the rear edge of the cover 2, with the spring 9 put around the screw 23 between the turning head 7 and the collar 8. A front end of the turning head 7 is rotatably connected to the collar 8.

With the above arrangements, the cover 2 may be freely pulled and pushed relative to the mainframe case 1 to an open and a close position, respectively. When the cover 2 is fully pushed to the close position on the mainframe case 1, the turning heads 7 and accordingly the screws 23 may be turned to lock the cover 2 to the mainframe case 1.

In FIG. 1, there is shown an embodiment of the present invention implemented on a vertical mainframe case 1 and the cover 2 is located at one lateral side of the case 1. It is understood the present invention is also applicable to a horizontal mainframe case with similar structure, principle, and operational manner as the embodiment illustrated in the drawings.

The present invention has been described with a preferred embodiment thereof and it is understood that many changes and modifications in the described embodiment can be carried out without departing from the scope and the spirit of the invention as defined by the appended claims.

What is claimed is:

1. A mainframe case with sliding cover openable in multiple stages, comprising a mainframe case having one side formed into a movable cover; said mainframe case being provided at upper and lower edges of said side to where said cover is mounted with a pair of outward-faced fixed channels, each of said fixed channels having a first-stage sliding rail mounted therein to slide relative to said fixed channel; and said cover being fixedly provided at inner upper and inner lower edges corresponding to said two fixed channels with two second-stage sliding rails adapted to separately slide in and relative to said first-stage sliding rails, such that said cover is assembled to and movable relative to said mainframe case between an open and a close position through sliding engagement of said second-stage sliding rails with said first-stage sliding rails.

2. The mainframe case with sliding cover openable in multiple stages as claimed in claim 1, further comprising an intermediate sliding rail mounted between said first-stage and second-stage sliding rails at the same upper or lower edge of said cover; said intermediate sliding rail being provided with slide-assisting means for said intermediate sliding rail to smoothly slide between and relative to said first-stage and said second-stage sliding rail.

3. The mainframe case with sliding cover openable in multiple stages as claimed in claim 2, wherein said slide-assisting means provided on said intermediate sliding rails are balls rotatably contacting with inner wall surfaces of said first-stage and said second-stage sliding rails.

4. The mainframe case with sliding cover openable in multiple stages as claimed in claim 2, wherein each of said first-stage rails is provided near both ends with first stop means for stopping each said intermediate sliding rail from sliding off and accordingly completely separating from said first-stage sliding rail.

5. The mainframe case with sliding cover openable in multiple stages as claimed in claim 3, wherein each of said first-stage rails is provided near both ends with first stop means for stopping each said intermediate sliding rail from sliding off and accordingly completely separating from said first-stage sliding rail.

6. The mainframe case with sliding cover openable in multiple stages as claimed in claim 4, wherein said first stop means near each end of said first-stage sliding rail are two opposite protrusions provided on two inner wall surfaces of said first-stage sliding rail to project into said first-stage sliding rail.

7. The mainframe case with sliding cover openable in multiple stages as claimed in claim 5, wherein said first stop means near each end of said first-stage sliding rail are two opposite protrusions provided on two inner wall surfaces of said first-stage sliding rail to project into said first-stage sliding rail.

8. The mainframe case with sliding cover openable in multiple stages as claimed in claim 2, wherein each of said second-stage sliding rails is provided near two ends with second stop means for preventing said second-stage sliding rail from sliding off and accordingly completely separating from said intermediate sliding rail.

9. The mainframe case with sliding cover openable in multiple stages as claimed in claim 3, wherein each of said second-stage sliding rails is provided near two ends with second stop means for preventing said second-stage sliding rail from sliding off and accordingly completely separating from said intermediate sliding rail.

10. The mainframe case with sliding cover openable in multiple stages as claimed in claim 8, wherein said second stop means near each end of said second-stage sliding rail is an upward projected stop plate formed by upward punching a bottom of said second-stage sliding rail.

11. The mainframe case with sliding cover openable in multiple stages as claimed in claim 9, wherein said second stop means near each end of said second-stage sliding rail is an upward projected stop plate formed by upward punching a bottom of said second-stage sliding rail.

12. The mainframe case with sliding cover openable in multiple stages as claimed in claim 1, wherein each of said fixed channels has a spring strip removably mounted therein at a predetermined position, and each said spring strip having a flat long segment and a bent short segment located at a front end of said flat long segment to form a hook portion; and wherein each said first-stage sliding rail is provided near a front end with a stop opening adapted to engage with said hook portion formed at said bent short segment of said spring strip when said cover is pulled rearward to the open position and thereby prevent said first-stage sliding rail from sliding off and completely separating from said fixed channel.

13. The mainframe case with sliding cover openable in multiple stages as claimed in claim 1, wherein said cover is provided on a rear edge with locking assemblies; each of said locking assemblies being connected to a screw that could be threaded into said rear edge of said cover to lock said cover in said close position to said mainframe case.
